(19) United States
(12) Patent Application Publication
(10) Pub. No.: US 2012/0249344 A1
(43) Pub. Date: Oct. 4, 2012

(54) MULTI-COLOR ILLUMINATED KEYBOARD

(76) Inventor: Chin-Wen CHOU, New Taipei City (TW)

(21) Appl. No.: 13/074,461

(22) Filed: Mar. 29, 2011

(51) Int. Cl. H03M 11/00

(52) U.S. Cl. 341/22

(57) ABSTRACT

A multi-color illuminated keyboard at least includes a plurality of keys, an array circuit board, a signal processing unit and a lighting control processor. The array circuit board is located beneath the keys and triggered by depressing one key to generate a corresponding array signal or a mode switching signal. The signal processing unit receives the array signal and converts the array signal into a character signal to be output. The signal processing also can receive the mode switching signal and transmit the mode switching signal to the lighting control processor. The lighting control processor presets multiple driving modes and is electrically connected to the lighting element sets in the illuminated keyboard. The lighting control processor can be triggered by the mode switching signal to change the driving modes of the lighting element sets in the illuminated keyboard.

### FIELD OF THE INVENTION

The present invention relates to a multi-color illuminated keyboard and particularly to an illuminated keyboard equipped with an improved light emission driving circuit.

### BACKGROUND OF THE INVENTION

Keyboards have been widely used as computer input devices. In recent years, illuminated keyboards also have been developed to provide illumination function, such as U.S. Pat. Nos. 6,284,988, 6,199,996 and 6,554,442. They respectively have a light guide board in a keyboard to transmit and project light outwards to allow users to recognize key locations in a dark or low illumination environment to avoid erroneous keystrokes.

Aside from providing illumination, illuminated keyboards capable of generating color-light alterations also have been developed, such as R.O.C. utility model No. M256532 which discloses a multi-color illuminated keyboard. It includes a plurality of keys and a multi-color cold light board. The multi-color cold light board has a plurality of lighting zones to generate different color lights. Moreover, the lighting zones can correspond to different key sets (such as functional keys, numeric keys, directional keys and the like) to allow the different types of key sets to provide different backlight colors to facilitate user recognition.

R.O.C. utility model No. M256976 also discloses a multi-color illuminated keyboard. It comprises a main body, a cold light sheet with multi-color lighting segments and a circuit element. The main body has an upper lid, an elastic trigger layer, a pliable circuit board, a plurality of keys and a baseboard. The keys are positioned at preset locations of the upper lid and are light transmissive. The cold light sheet is located between the elastic trigger layer and circuit board. The circuit board is connected to a power output end of the cold light sheet to provide power required by the cold light sheet. The cold light sheet has multiple segmented color layers to emit light with different colors.

All the aforesaid conventional techniques divide the keyboard into multiple lighting zones. In the event that the lighting zones have to possess various light colors, independent lighting time and independent trigger signals, the keyboard needs to install a control circuit to support light source driving.

R.O.C. patent No. 468838 entitled “Multimedia computer keyboard” discloses a multifunctional keyboard which comprises a keyboard, a control key module and a modular switch key. The keyboard includes a microprocessor to support 8×18 scan array. Namely the microprocessor has at least 26 input pins to support the 8×18 scan array. However, in addition to the scan array corresponding to each key, the microprocessor also includes other pins for output, power receiving, grounding and the like. The expandability of the microprocessor depends on the number of pins and density (capacity) of the internal circuit.

To incorporate with the control function of multiple lighting zones in the aforesaid illuminated keyboards, the number of pins and circuit capacity of the microprocessor in the conventional keyboards are inadequate and result in deficient lighting modes for the lighting zones. Illumination is monotonous. To provide more versatile lighting modes for the lighting zones or support more lighting zones, the expansion deficiency of the microprocessor in the conventional keyboards has to be resolved.

### SUMMARY OF THE INVENTION

In view of the microprocessor in the conventional illuminated keyboards has constraints on size, number of pins and cost to result in deficiency of the number of lighting element sets or driving modes that are driven by the microprocessor to make inadequacy of the microprocessor in the keyboard, the primary object of the present invention is to provide an illuminated keyboard equipped with a control circuit capable of driving a plurality of lighting element sets and also providing more control modes to drive the lighting element sets at the same time.

The present invention provides a multi-color illuminated keyboard which at least includes a plurality of keys, an array circuit board, a signal processing unit and a lighting control processor. The array circuit board is located beneath the keys and triggered by depression of one key to generate a corresponding array signal or a mode switching signal. The signal processing unit receives the array signal and converts the array signal into a character signal to be output, and it also can receive the mode switching signal and transmit the mode switching signal to the lighting control processor. The lighting control processor presets multiple driving modes and is electrically connected to the lighting element sets in the illuminated keyboard, and is triggered by the mode switching signal to change the driving modes of the lighting element sets.

The invention is characterized in changing the signal processing unit and installing the lighting control processor, in which a small number of pins of the signal processing unit is used to output the mode switching signal. The lighting control processor provides a plurality of driving modes and pins that are electrically connected to the lighting element sets. Design complexity and cost of a control chip are reduced. The lighting element sets also provide more versatile lighting modes to offer more flexible color-light alterations.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the illuminated keyboard of the invention.

FIG. 2 is a perspective view of the illuminated keyboard of the invention.

FIG. 3 is a circuit block diagram of an embodiment of the invention.

FIG. 4 is a circuit block diagram of another embodiment of the invention.

### DETAILED DESCRIPTION OF THE PREFERRED EMBODIMENTS

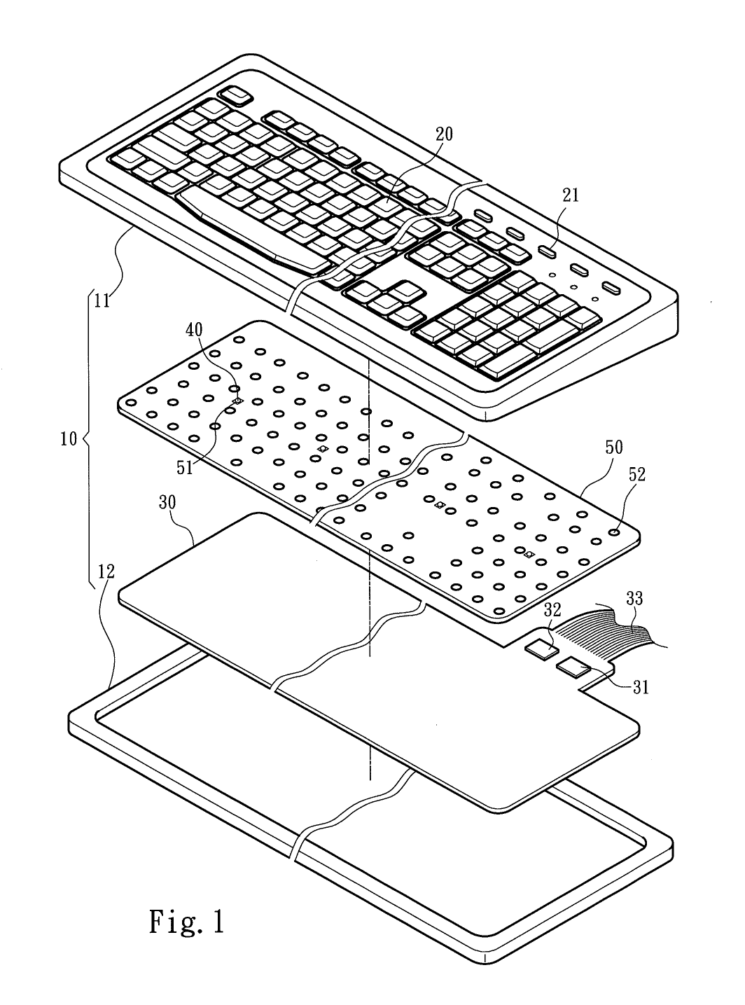

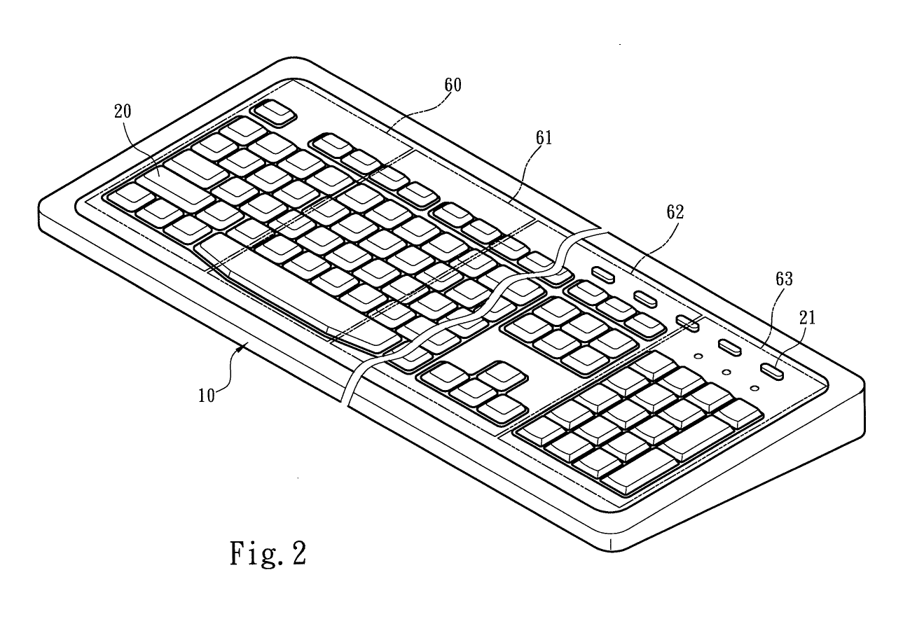

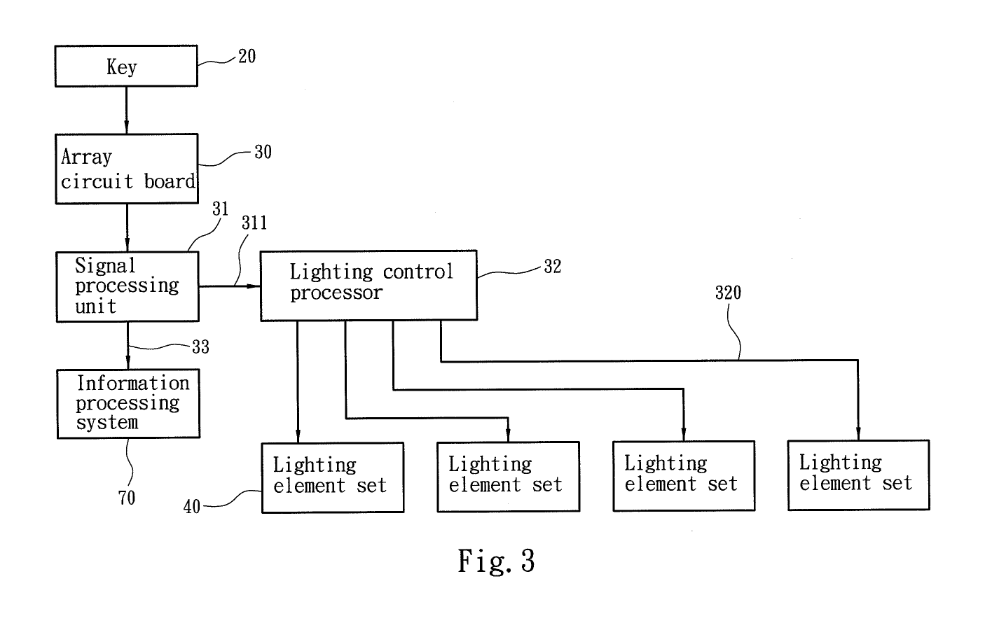

Please refer to FIGS. 1, 2 and 3 for an embodiment of the illuminated keyboard of the invention. The illuminated keyboard includes a housing 10 consisting of a top lid 11 and a bottom lid 12 coupled together. The top lid 11 has openings to hold a plurality of keys 20. The top lid 11 and bottom lid 12 are interposed by an array circuit board 30, a light guide board 50 located between the keys 20 and array circuit board 30, and a plurality of lighting element sets 40 located in the housing 10. The light guide board 50 has a plurality of housing troughs 51 to hold the lighting element sets 40 and a plurality of apertures 52 corresponding to the keys 20. Through different positions and light projection ranges of the lighting element sets 40, the illuminated keyboard is divided into a plurality of lighting zones 60, 61, 62 and 63. Each lighting element set 40 is located in one lighting zone 60, 61, 62 or 63. Each lighting zone 60, 61, 62 or 63 covers a plurality of non-repeated keys. The array circuit board 30 is located beneath the keys 20 and has a plurality of signal contacts corresponding to the keys 20. When being depressed, each key 20 is connected to one signal contact to generate a corresponding array signal. Moreover, the openings of the top lid 11 hold at least one mode switch key 21. The array circuit board 30 may also have a signal contact corresponding to the mode switch key 21. When being depressed, the mode switch key 21 triggers the array circuit board 30 to generate a mode switching signal. The array circuit board 30 further is coupled with a signal processing unit 31, a lighting control processor 32 and an output cable 33.

The signal processing unit 31 receives the array signal and converts the array signal into a character signal to be output to an information processing system 70 through the output cable 33. The information processing system 70 can be a mobile phone, computer or other devices including an operation system operated by users. The signal processing unit 31 includes at least one mode switch pin 311 electrically connected to the lighting control processor 32. The signal processing unit 31 outputs the mode switching signal through the mode switch pin 311 to the lighting control processor 32. The lighting control processor 32 presets a plurality of driving modes and has a plurality of driving signal pins 320. Each driving signal pin 320 is electrically connected to one lighting element set 40. Through the driving signal pins 320, the driving signals are provided to drive the lighting element sets 40. By pressing the mode switch key 21, the signal processing unit 31 outputs the mode switching signal. The lighting control processor 32 receives the mode switching signal and is triggered to change the driving modes of the lighting element sets 40 in the illuminated keyboard.

The invention set forth above provides features as follows: the lighting control processor 32 drives the lighting element sets 40 to emit light. The signal processing unit 31 not only outputs the character signal according to the triggered contact on the array circuit board 30, but also outputs the mode switching signal through a smaller number of the mode switch pins 311. The lighting control processor 32 also has more room to accommodate the driving signal pins 320 to drive more lighting element sets 40. Furthermore, the lighting control processor 32 has sufficient room to hold circuits or memory to support multiple driving modes. Thus the invention can overcome the problems of the conventional keyboards having inadequate pin number and circuit capacity of the microprocessor. In addition, by supporting more lighting element sets 40, the lighting control processor 32 can provide more flexible color-light alterations. Moreover, the lighting element sets 40 include a plurality of lighting elements to provide different color lights. The driving modes include an alternate color changing mode with the lighting control processor 32 sending multiple varying driving signals to drive the lighting element sets 40 to change colors alternately, an alternate igniting mode with the lighting control processor 32 sending multiple driving signals in different time series to drive the lighting element sets 40 to ignite in different time series; and a brightness-darkness cycling mode with the lighting control processor 32 sending multiple varying driving signals to drive the lighting element sets 40 to generate different illumination intensity from brightness to darkness in an alternate fashion. While the aforesaid embodiment defines the mode switching signal is generated by pressing the mode switch key 21 to trigger the array circuit board 30, the mode switch key 21 can also be omitted from the illuminated keyboard. In such a condition, the keys 20 include a key combination depressed to trigger the array circuit board 30 to generate the mode switching signal. The key combination consists of at least two keys 20.

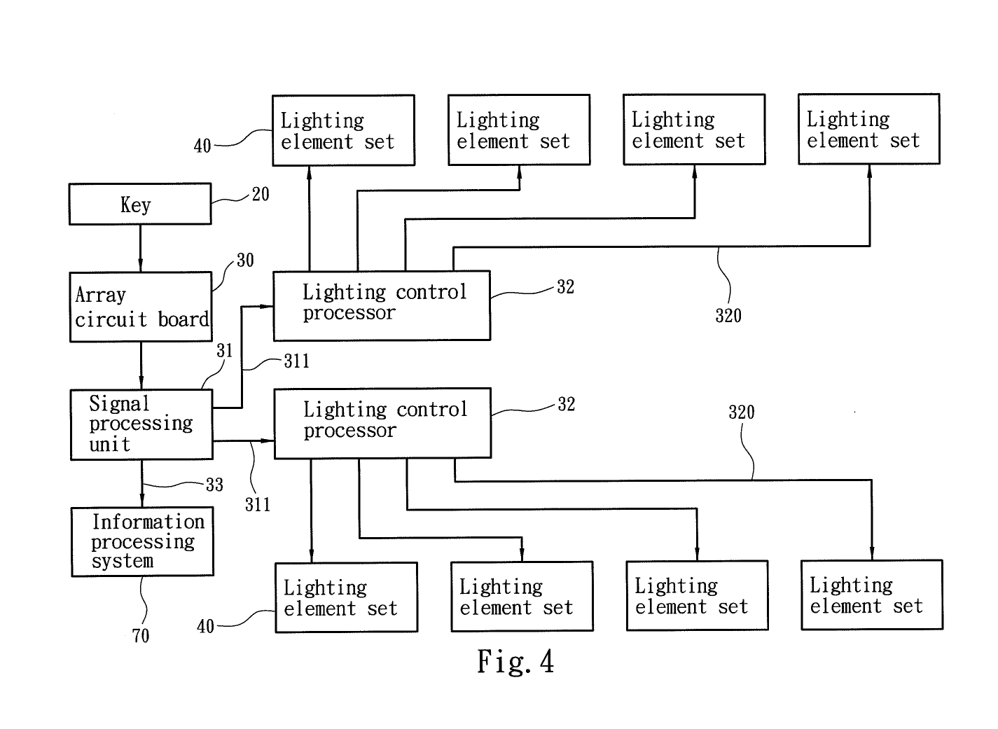

Also referring to FIG. 4, the signal processing unit 31 requires only a small number of mode switch pins 311 to connect to the lighting control processor 32 to drive the lighting element sets 40. Hence the signal processing unit 31 can spare extra mode switch pins 311 to connect to another lighting control processor 32 to drive other lighting element sets 40. Thus the mode switching pins 311 can send the mode switching signals simultaneously to control the two lighting control processors 32 to change the driving modes.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

In summation of the above description, the present invention provides a significant improvement over the conventional techniques and complies with the patent application requirements, and is submitted for review and granting of the commensurate patent rights.

What is claimed is:

1. A multi-color illuminated keyboard, comprising:
a plurality of keys;
an array circuit board triggered by depressing the keys to generate a corresponding array signal or a mode switching signal;
a signal processing unit which receives the array signal and converts the array signal into a character signal to be output and includes at least one mode switch pin to output the mode switching signal; and
a lighting control processor which presets multiple driving modes and is electrically connected to the mode switch pin to be triggered by the mode switching signal to change the driving modes for driving multiple lighting element sets located in the illuminated keyboard.

2. The multi-color illuminated keyboard of claim 1, wherein the keys include at least one mode switch key depressed to trigger the array circuit board to generate the mode switching signal.

3. The multi-color illuminated keyboard of claim 1, wherein the keys include a key combination depressed to trigger the array circuit board to generate the mode switching signal, the key combination including at least two keys.

4. The multi-color illuminated keyboard of claim 1, wherein the illuminated keyboard is divided into a plurality of lighting zones, each lighting element set being located in one lighting zone.

5. The multi-color illuminated keyboard of claim 4, wherein the lighting zones cover a plurality of non-repeated keys.

6. The multi-color illuminated keyboard of claim 1, wherein the driving modes include a brightness-darkness cycling mode in which the lighting control processor outputs a plurality of varying driving signals to drive the lighting element sets to generate different illumination intensity from brightness to darkness in an alternate fashion.

7. The multi-color illuminated keyboard of claim 1, wherein the driving modes include an alternate igniting mode in which the lighting control processor outputs a plurality of driving signals in different time series to drive the lighting element sets to ignite in different time series.

8. The multi-color illuminated keyboard of claim 1, wherein the lighting element sets include a plurality of lighting elements to provide different color lights, the driving modes including an alternate color changing mode in which the lighting control processor outputs multiple varying driving signals to drive the lighting element sets to change colors alternately.

9. The multi-color illuminated keyboard of claim 1, wherein the lighting control processor includes a plurality of driving signal pins, each driving signal pin being electrically connected to one lighting element set.
